(19) United States
(12) Patent Application Publication
(10) Pub. No.: US 2024/0030174 A1
(43) Pub. Date: Jan. 25, 2024

(54) QUAD FLAT NO-LEAD (QFN) PACKAGE WITH BACKSIDE CONDUCTIVE MATERIAL AND DIRECT CONTACT INTERCONNECT BUILD-UP STRUCTURE AND METHOD FOR MAKING THE SAME

(71) Applicant: Deca Technologies USA, Inc., Tempe, AZ (US)

(72) Inventors: Timothy L. Olson, Phoenix, AZ (US); Robin Davis, Vancouver, WA (US); Paul R. Hoffman, San Diego, CA (US); Clifford Sandstrom, Richfield, MN (US)

(21) Appl. No.: 18/224,964

(22) Filed: Jul. 21, 2023

Related U.S. Application Data
(63) Continuation-in-part of application No. 17/957,936, filed on Sep. 30, 2022.
Application No. 17/957,936 is a continuation-in-part of application No. 17/957,683, filed on Sep. 30, 2022, now Pat. No. 11,749,534.
(60) Provisional application No. 63/455,947, filed on Mar. 30, 2023.
(60) Provisional application No. 63/391,315, filed on Jul. 21, 2022.
(60) Provisional application No. 63/391,315, filed on Jul. 21, 2022.

(51) Int. Cl. H01L 23/00; H01L 23/31; H01L 25/10; H01L 25/065

(52) U.S. Cl. CPC H01L 24/20; H01L 24/32; H01L 24/29; H01L 23/3135; H01L 25/105; H01L 24/19; H01L 25/0655; H01L 24/24; H01L 24/25; H01L 2225/1047; H01L 23/293

(57) ABSTRACT

The disclosure concerns electronic assemblies, comprising: a component comprising conductive studs on a surface of the component; a first encapsulant disposed around four side surfaces of the component, over the surface of the component, and around at least a portion of sidewalls of the conductive studs; a conductive backside material disposed over at least a portion of a backside of the component; a substantially planar surface disposed over the surface of the component, wherein the substantially planar surface comprises ends of the conductive studs and a planar surface of the first encapsulant, wherein the planar surface of the first encapsulant comprises a roughness less than 500 nanometers over a characteristic measurement distance; conductive structures disposed over the planar surface and configured to be electrically coupled with the component; a second encapsulant disposed over the conductive structures; and conductive pads disposed over, or within, the second encapsulant for TO interconnection.

### CROSS-REFERENCE TO RELATED APPLICATIONS

This application claims the benefit of U.S. Provisional Application No. 63/455,947, entitled “Quad Flat No-Lead (QFN) Package with Backside Thermally Conductive Material and Direct Contact Interconnect Build-Up Structure and Method for Making the Same” which was filed Mar. 30, 2023, the entire disclosure of which is hereby incorporated herein by this reference.

This application is a continuation-in-part of U.S. patent application Ser. No. 17/957,936, entitled “Quad Flat No-Lead (QFN) Package Without Leadframe and Direct Contact Interconnect Build-Up Structure” which was filed Sep. 30, 2022, which application claims the benefit of U.S. Provisional Application No. 63/391,315 entitled “Quad Flat No-Lead (QFN) Package Without Leadframe and Direct Contact Interconnect Build-up Structure Without Capture Pads and Method for Making the Same” which was filed Jul. 21, 2022, the entire disclosures of which are hereby incorporated herein by this reference.

This application is a continuation-in-part of U.S. patent application Ser. No. 17/957,683, entitled “Quad Flat No-Lead (QFN) Package Without Leadframe and Direct Contact Interconnect Build-Up Structure and Method for Making the Same” which was filed Sep. 30, 2022, which application claims the benefit of U.S. Provisional Application No. 63/391,315 entitled “Quad Flat No-Lead (QFN) Package Without Leadframe and Direct Contact Interconnect Build-up Structure Without Capture Pads and Method for Making the Same” which was filed Jul. 21, 2022, the entire disclosures of which are hereby incorporated herein by this reference.

### INCORPORATION BY REFERENCE

This disclosure hereby incorporates by reference the entirety of the disclosures of: (i) U.S. Patent Application No. 63/347,516 entitled “Molded Direct Contact Interconnect Build-Up Structure Without Capture Pads” to Davis et al. that was filed on May 31, 2022; (ii) U.S. patent application Ser. No. 13/891,006, titled “Semiconductor Device and Method of Adaptive Patterning for Panelized Packaging,” filed May 9, 2013, and issued as U.S. Pat. No. 9,196,509; and (iii) U.S. patent application Ser. No. 13/893,117, titled “Adaptive Patterning for Panelized Packaging,” filed May 13, 2013, and issued as U.S. Pat. No. 8,826,221.

### TECHNICAL FIELD

Embodiments of the present disclosure relate to the field of devices and methods of forming an electronic assembly or semiconductor assembly, such as quad flat no-lead (QFN), dual flat no-lead (DFN) or small-outline no-lead (SON) semiconductor packaging without a leadframe, as well as LGA packages, BGA packages, and other “no-lead” packages, with or without molded direct contact interconnect build-up structures or multi-layer structures without capture pads.

### BACKGROUND

Semiconductor assemblies, devices, packages, substrates, and interposers are commonly found in modern electronic products. Production of semiconductor devices involves a multistep build-up of components. Conventional interconnect structures alternate dielectric and conductive layers. An opening or via is created in the dielectric to allow connectivity from one conductive layer to another. On the conductive layers, capture pads are required for the vias to compensate for overlay or other dimensional variations which typically occur during manufacture. Use of these conventional capture pads impacts the ability to construct compact or high-density structures due to limits on routing density. Additionally, the process for opening vias limits the size and shape of the connections between conductive layers.

### SUMMARY

An opportunity exists for improved semiconductor assemblies, including applications for semiconductor manufacturing. Accordingly, in some aspects, the disclosure concerns electronic assemblies comprising a quad flat no-lead (QFN), dual flat no-lead (DFN) or small outline no-lead (SON) package, an LGA package, or a BGA package without a leadframe, comprising: a semiconductor chip comprising conductive studs over an active layer of the semiconductor chip. A first encapsulant may be disposed as a single layer of material around four side surfaces of the semiconductor chip, over the active layer of the semiconductor chip, and around at least a portion of sidewalls of the conductive studs. A thermally conductive backside material may be disposed over a backside of the semiconductor chip. A substantially planar surface may be disposed over the active layer of the semiconductor chip, wherein the substantially planar surface comprises ends of the conductive studs and a planar surface of the first encapsulant. The planar surface of the first encapsulant may comprise a roughness less than 500 nanometers (nm) over a characteristic measurement distance. Conductive structures may be disposed over the planar surface and configured to be electrically coupled with the semiconductor chip. A second encapsulant may be disposed over the conductive structures. Conductive pads may be disposed over the second encapsulant in the form contact pads.

In some embodiments, the thermally conductive backside material comprises metal. In certain embodiments, the thermally conductive backside material comprises copper with a thickness in a range of 1,000 angstroms to 200 μm. Some electronic assemblies may have thermally conductive backside material that extends across a backside of the semiconductor chip and a backside of the encapsulant.

The thermally conductive backside material may extend to an edge of the electronic assembly. In other embodiments, the thermally conductive backside material further comprises a pull back from an edge of the electronic assembly.

In some electronic assemblies, the thermally conductive backside material may be electrically isolated from the semiconductor chip. In other electronic assemblies, the thermally conductive backside material may be configured to be electrically connected to the semiconductor chip.

In some embodiments, the electronic assembly further comprises a via or a diffusion with a silicide contact coupled with the active layer and extending to the backside of the semiconductor chip.

In some embodiments, the thermally conductive backside material may be patterned to provide a first portion of material that is configured to be electrically coupled with the component and a second portion of material that is electrically isolated from the component.

In certain embodiments, the electronic assembly may further comprise a semiconductor chip, a Micro-Electro-Mechanical Systems (MEMS), an optical component, an IPD, an active or passive bridge die, an interposer, or an embedded device.

The conductive pads may comprise one or more of an input electrical contact, an output electrical contact, an IO contact, a power contact, a ground contact, a clock contact, electrical contacts, a bump, a solder ball, a solder bump, a BGA, a LGA, land pads, copper pillars, and copper pillars with solder, to couple with devices outside the electronic assembly.

Some electronic assemblies are formed without exposed copper.

Certain electronic assemblies further comprising a plurality of dummy thermal conductive studs disposed over the active layer of the semiconductor chip and thermally coupling the dummy thermal conductive studs with a thermally conductive layer on the QFN package, DFN package, SON package, LGA package, or BGA package.

Some electronic assemblies further comprise a thermally conductive flag disposed over the second encapsulant and over at least a portion of the surface of the component.

In some embodiments, the electronic assembly further comprises one or more of a solderable metal system (SMS), an organic solderability preservative (OSP), oxidation-resistant metal or metal alloy, or solder ball disposed over the conductive pads, thermally conductive flag, and thermally conductive backside material to resist oxidation over at least a portion of the conductive pads.

Other aspects concern electronic assemblies comprising a component comprising conductive studs formed over a surface of the component. A first encapsulant may be disposed as a single layer of material around four side surfaces of the component, over the surface of the component, and around at least a portion of sidewalls of the conductive studs. A conductive backside material may be disposed over at least a portion of a backside of the component. A substantially planar surface may be disposed over the surface of the component, wherein the substantially planar surface comprises ends of the conductive studs and a planar surface of the first encapsulant. The planar surface of the first encapsulant may comprise a roughness less than 500 nanometers (nm) over a characteristic measurement distance. Conductive structures may be disposed over the planar surface and configured to be electrically coupled with the component. A second encapsulant may be disposed over the conductive structures. Conductive pads may be disposed over, or within, the second encapsulant for IO interconnection. In some instances, the IO interconnection will comprise one or more of a signal contact, a power contact, a ground contact, a source contact, a clock contact, a drain, a gate, an emitter, a collector, a base, a cathode, an anode, electrical contacts, a bump, a solder ball, a solder bump, a BGA, a LGA, land pads, copper pillars, and copper pillars with solder, to couple with devices outside the electronic assembly. In some embodiments, the conductive structure is a trace, a pad, or an electrode. In some embodiments, the conductive studs are recessed below the planar surface by 1-1,000 nanometers (nm) or 200-300 nm.

Some electronic assemblies further comprise one or more of a solderable metal system (SMS), an organic solderability preservative (OSP), or oxidation-resistant metal or metal alloy, or solder ball disposed over one or more of the conductive pads, a conductive flag, and the conductive backside material to resist oxidation.

In some embodiments, the conductive backside material comprises metal. In certain embodiments, the conductive backside material comprises copper with a thickness in a range of 1,000 angstroms to 200 μm.

In some electronic assemblies, the conductive backside material extends across a backside of the component and a backside of the encapsulant.

Some electronic assemblies further comprise: a portion of the component being formed as an active layer of a semiconductor component; and a diffusion with a silicide contact (may use tungsten or other suitable material) or a via coupled with the active layer and extending to the backside of the component.

In some embodiments, the conductive backside material is patterned to provide a first portion of material that is configured to be electrically coupled with the component and a second portion of material that is electrically isolated from the component.

Some electronic assemblies additionally comprise a through mold conductive interconnect between a top and bottom conductive flag or conductive layer.

Certain electronic assemblies comprise a face up component and a face down component within the electronic assembly.

### BRIEF DESCRIPTION OF THE FIGURES

FIG. 1A shows a plan or top view of a substrate, which may comprise a semiconductor wafer or native wafer with a base substrate material.

FIG. 1B illustrates a cross-sectional view of a portion of semiconductor wafer.

FIG. 1C further illustrates an optional adhesive or a (chip) die attach film (DAF) or material may be attached to the back surface of the component, such as for subsequent mounting on a carrier.

FIG. 2A illustrates a plan or top view of the temporary carrier.

FIG. 2B illustrates a cross-sectional side view in which the components (from FIG. 1C) are disposed face up over a temporary carrier.

FIG. 2C illustrates a close-up view of the component taken at section marker 2E of FIG. 2B.

FIG. 2D continuing from FIGS. 2B and 2C, illustrates disposing an encapsulant around the component face-up over a temporary carrier around four side surfaces of the component, over the active layer of the components, and around the conductive studs.

FIG. 3A illustrates a perspective view of an embodiment of a QFN package with a cross-section through a center of the package.

FIG. 3B and FIG. 3C illustrate one or more layers of QFN, DFN, or SON packages that may also comprise other desired assemblies.

FIG. 4A illustrates an instance in which the thermally conductive backside material extends to an edge of the semiconductor assembly (or electronic assembly).

FIG. 4B illustrates an instance in which the thermally conductive backside material further comprises a pull back from an edge of the electronic assembly, and the backside material is formed over (or after) the encapsulant is formed around the semiconductor chip.

FIG. 4C illustrates an instance in which the thermally conductive backside material also comprises a pull back from an edge of the electronic assembly, and the backside material is formed over at least partially embedded within the encapsulant.

FIG. 4D illustrates an example wherein at least a portion of the thermally conductive backside material is configured to be electrically connected to the semiconductor chip.

FIG. 4E illustrates an instance in which the electronic assembly may further comprise a via formed within the semiconductor chip or embedded device, the via being coupled with, or extending through, the active layer and extending to the backside of the semiconductor chip.

FIG. 4F illustrates an instance in which the electronic assembly may further comprise a via formed within the semiconductor chip or embedded device, the via being coupled with, or extending through, the active layer and extending to the backside of the semiconductor chip.

FIG. 5A illustrates both the insulating layer and the conductive backside material extending to a package or assembly edge.

FIG. 5B illustrates both the insulating layer and the conductive backside material extending to a package or assembly edge.

FIG. 5C illustrates an arrangement similar to FIG. 4B with a pull back for the conductive backside material and similar to FIG. 5A with the insulating layer extending to the package edge.

FIG. 5D illustrates an arrangement similar to FIG. 4C with a pull back for the conductive backside material.

FIG. 5E illustrates an arrangement similar to FIG. 4E by illustrating instances in which the electronic assembly may further comprise a via formed within the semiconductor chip or embedded device.

FIG. 6A illustrates an isometric view of an assembly or semiconductor assembly (which may comprise one or more components 14 disposed therein) mounted to a substrate or PCB.

FIG. 6B illustrates an isometric view of the assembly or semiconductor assembly shown above in FIG. 6A, but differs from FIG. 6A by illustrating the assembly not being mounted to the substrate or PCB.

FIG. 6C illustrates an isometric view of the assembly from the reverse view of what was shown in FIGS. 6A and 6B, with a frontside of the assembly oriented upwards to display multiple thermal and electrical frontside conductive pads and single backside thermally conductive material displayed at the bottom or lower portion of FIG. 6C.

FIG. 7A illustrates an isometric view of an assembly or semiconductor assembly (which may comprise one or more components) mounted to a substrate or PCB, similar to that shown in FIG. 6A. FIG. 7A differs from FIG. 6A by showing more than one conductive backside material at the topside of the mounted assembly, wherein the conductive backside material is thermally conductive, or thermally and electrically conductive.

FIG. 7B illustrates an isometric view of the assembly from the reverse view of what was shown in FIG. 7A.

FIG. 8A illustrates a cross-sectional profile view of a multi-component assembly comprising a single or shared conductive backside material, and a shared frontside conductive material.

FIG. 8B illustrates another cross-sectional view of an assembly similar to that shown in FIG. 8A. FIG. 8B differs from FIG. 8A by comprising multiple separate or isolated (not shared) conductive frontside materials disposed over the components.

FIG. 8C illustrates another cross-sectional view of an assembly similar to that shown in FIG. 8B. FIG. 8C differs from FIG. 8B by comprising multiple separate or isolated (not shared) backside materials disposed over the components.

FIG. 9A illustrates the thermally conductive backside material may be patterned to provide a first portion of material that is configured to be electrically coupled with the component and a second portion of material that is electrically isolated from the component.

FIG. 9B illustrates the thermally conductive backside material may be patterned to provide a first portion of material that is configured to be electrically coupled with the component and a second portion of material that is electrically isolated from the component.

FIGS. 10A and 10B illustrate assemblies comprising conductive material and multiple components disposed therein at different orientations.

FIG. 11 illustrate an assembly similar to that shown in FIG. 10A mounted to a substrate or PCB.

FIGS. 12A-12D illustrate various plan views in which unit specific patterning is used within assemblies similar to those shown in the preceding FIGs.

### DETAILED DESCRIPTION

Detailed aspects and applications of the disclosure are described below in the following drawings and detailed description of the technology. Unless specifically noted, it is intended that the words and phrases in the specification and the claims be given their plain, ordinary, and accustomed meaning to those of ordinary skill in the applicable arts.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The singular forms “a,” “an,” and “the” include plural referents unless the context clearly dictates otherwise. Thus, for example, reference to “a step” includes reference to one or more of such steps.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

Throughout the description and claims of this specification, the words “comprise” and “contain” and variations of the words, for example “comprising” and “comprises”, mean “including but not limited to”, and are not intended to (and do not) exclude other components.

As required, detailed embodiments of the present disclosure are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

Unless specifically noted, it is intended that the words and phrases in the specification and the claims be given their plain, ordinary, and accustomed meaning to those of ordinary skill in the applicable arts. The inventors are fully aware that they can be their own lexicographers if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning. Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112(f). Thus, the use of the words “function,” “means” or “step” in the Detailed Description or Description of the Drawings or claims is not intended to somehow indicate a desire to invoke the special provisions of 35 U.S.C. § 112(f), to define the invention. To the contrary, if the provisions of 35 U.S.C. § 112(f) are sought to be invoked to define the inventions, the claims will specifically and expressly state the exact phrases “means for” or “step for”, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of 35 U.S.C. § 112(f). Moreover, even if the provisions of 35 U.S.C. § 112(f) are invoked to define the claimed aspects, it is intended that these aspects not be limited only to the specific structure, material or acts that are described in the preferred embodiments, but in addition, include any and all structures, materials or acts that perform the claimed function as described in alternative embodiments or forms of the disclosure, or that are well known present or later-developed, equivalent structures, material or acts for performing the claimed function.

The foregoing and other aspects, features, and advantages will be apparent to those of ordinary skill in the art from the specification, drawings, and the claims.

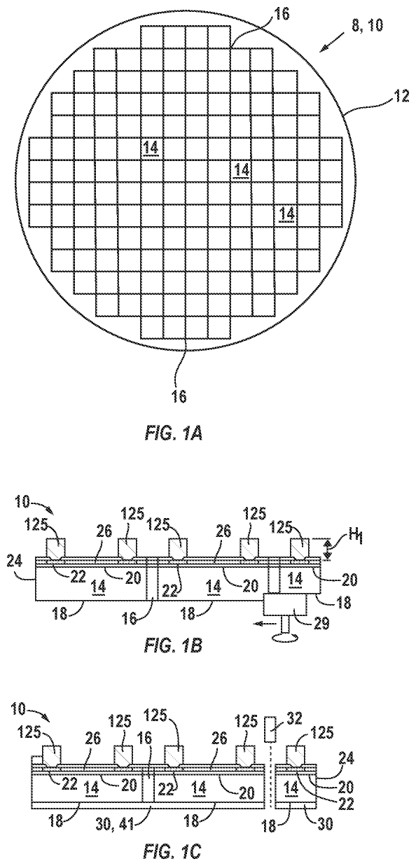

This disclosure relates to packages used to house components. While much of the description will refer to a quad flat no-lead (QFN), dual flat no-lead (DFN) or small-outline no-lead (SON) package without a leadframe and with molded direct contact interconnect build-up structures (and a method of making the same) for purposes of providing examples and embodiments, the disclosure is not limited to QFN, DFN or SON packages. The description and claims also include LGA packages with an area array of contact pads, as well as packages that are not “no-lead” packages—such as BGA packages. A QFN, DFN or SON is a small-sized integrated circuit (IC) package that offers small size, low cost, and very good performance. FIG. 1A, included illustrates an image of a conventional QFN package 500 with side lengths of 5 mm. Those of ordinary skill in the art are familiar with QFN, DFN and SON package structures.

No-lead packages such as QFN, DFN and SON packages physically and electrically connect to the surface of printed circuit boards (PCB's) or other substrates using surface mount technology, thus coupling the IC to the PCB or other substrate. In the surface mount technology represented in conventional QFN packages land pads are exposed on the upper surface of the package and on the side edges of the package. In particular, a portion of the leadframe, called the tie bar, is cut and exposed along the side edges during singulation of the packages. Additionally, when the packages are cut during singulation, because the land pads extend to the edge of the package, the saw creates a burr caused by the saw heat and rotation as it cuts along the edge of the land pads, wherein the burr extends from the land pads. This burring that extends in each of the X-, Y- and Z-planes is a known problem of QFN singulation and requires costly process measures to reduce them or additional processing to remove them.

FIG. 1A shows a plan or top view of a substrate 8, which may comprise a semiconductor wafer or native wafer 10 with a base substrate material 12, such as, without limitation, silicon, silicon dioxide, germanium, gallium arsenide, indium phosphide, gallium nitride, silicon nitride or silicon carbide, for the base material or structural support. A plurality of components or semiconductor components 14 can be formed on wafer 10 and be separated by a non-active, inter-component wafer area or saw street 16 as described above. The saw street 16 can provide cutting areas to singulate the semiconductor wafer 10 into the individual component 14. In other instances, integrated passive devices (IPDs), either passive or active bridge chips, or other suitable devices that become embedded devices can be formed on a substrate 8 formed of glass, ceramic, or other suitable material for providing structural support for subsequent processing.

Each component 14 may comprise one or more active devices, passive devices, or both active devices and passive devices. In some instances, the component 14 may be formed without active and passive devices, and be used for transmission or routing, such as by comprising TSVs for vertical interconnect. For example, the component 14 may be formed as a bridge chip with only electrical routing and with copper studs of the semiconductor chip electrically connected or coupled with wiring, routing, or RDL. The component 14 may also be only a dummy substrate with no electrical function, but rather act as structural element and may or may not include copper studs.

The component 14 comprises semiconductor chips and semiconductor die that comprise a backside or back surface 18 and an active layer 20 opposite the backside 18. In some instances, both faces of the component 14 will be active. In any event, the active layer contains one or more analog, or digital circuits implemented as active devices, conductive layers, and dielectric layers formed within or on the chip and electrically interconnected according to the electrical design and function of the semiconductor chip. In some instances, passive devices may also be integrated as part of the semiconductor chip or semiconductor die. The component 14 may comprise circuits that may include one or more transistors, diodes, and other circuit elements formed within the active layer to implement analog circuits or digital circuits, such as DSP, ASIC, memory, or other signal processing circuits. Digital circuits may include RF circuits, LED, LCOS, CIS, transistor, optoelectronic, MEMS and the like. The component 14 may also contain IPDs such as inductors, capacitors, and resistors, for RF signal processing, digital power line control or other functions. The component 14 may be formed on a native wafer. In some instances, a wafer level process may be used to produce many packages simultaneously on a carrier. In other instances, the package may be formed as part of a reconstituted wafer and may comprise multiple components or chips molded together.

FIG. 1B illustrates a cross-sectional view of a portion of semiconductor wafer 10. Each component 14 is shown comprising a backside or back surface 18 and an active layer 20 opposite the backside. However, as noted above, in some instances the component 14 may not comprise any active layer 20.

An electrically conductive layer or contact pads 22 is formed over active layer 20 using PVD, CVD, electrolytic plating, electroless plating process, or other suitable metal deposition process. Conductive layer 22 can be one or more layers of aluminum (Al), Titanium (Ti), copper (Cu), tin (Sn), nickel (Ni), gold (Au), palladium (Pd), silver (Ag), cobalt (Co), platinum (Pt), or other suitable electrically conductive material. Conductive layer 22 operates as contact pads or bond pads electrically coupled or connected to the circuits on active layer 20. Conductive layer 22 can be formed as contact pads disposed side-by-side a first distance from an edge 24 of component 14, as shown in FIG. 1B. Alternatively, conductive layer 22 can be formed as contact pads that are offset in multiple rows such that a first row of contact pads is disposed a first distance from the edge 24 of the component 14, and a second row of contact pads alternating with the first row is disposed a second distance from the edge 24 of the component 14. In other instances, the component 14 can comprise digital chips, analog chips, or RF chips (or other chips) with more than two rows of bond pads, and may further comprise bond pads 22 over the whole surface of the chip that do not follow a full grid pattern. Other components 14 may have bond pads in an array over the whole surface of the chip.

FIG. 1B also illustrates the semiconductor substrate 10 and components 14 can undergo an optional grinding operation with grinder 29 to reduce a thickness of the semiconductor substrate 10 and component 14.

FIG. 1B further shows one or more optional insulating, passivating, or dielectric layer 26 may be conformally applied over active layer 20 and over conductive layer 22. Insulating layer 26 can include one or more layers that are applied using PVD, CVD, screen printing, spin coating, spray coating, sintering, thermal oxidation, or other suitable process. Insulating layer 26 can contain, without limitation, one or more layers of silicon dioxide (SiO₂), silicon nitride (Si₃N₄), silicon oxynitride (SiON), tantalum pentoxide (Ta₂O₅), aluminum oxide (Al₂O₃), polymer, polyimide, benzocyclobutene (BCB), polybenzoxazoles (PBO), or other material having suitable insulating and structural properties. Alternatively, component 14 are packaged without the use of insulating layer 26. In another embodiment, insulating layer 26 includes a passivation layer formed over active layer 20 without being disposed over conductive layer 22. When insulating layer 26 is present and formed over conductive layer 22, openings are formed completely through insulating layer 26 to expose at least a portion of conductive layer 22 for subsequent mechanical and electrical interconnection. Alternatively, when insulating layer 26 is omitted, conductive layer 22 is exposed for subsequent electrical interconnection without the formation of openings.

FIG. 1B shows conductive studs or electrical interconnect structures 125 can be formed as conductive studs, bumps, thick pads, columns, pillars, posts, or conductive studs and are disposed over, and coupled or connected to, contact pads 22. The conductive studs 125 can be formed directly on contact pads 22 using patterning and metal deposition processes such as printing, PVD, CVD, sputtering, electrolytic plating, electroless plating, evaporation, or other suitable metal deposition process. Alternately, conductive studs 125 may be formed in a position not vertically over the pads 22 and connected by RDL. Conductive studs 125 can be one or more layers of Al, Cu, Sn, Ni, Au, Ag, palladium (Pd), or other suitable electrically conductive material and can include one or more UBM layers. In an embodiment, a photoresist layer can be deposited over component 14 and contact pads 22. A portion of the photoresist layer can be exposed and removed by a developing or other suitable process. Electrically conductive studs 125 can then be formed as pillars or other structures as previously described in the removed portion of the photoresist and over contact pads 22 using a plating process. In some embodiments, copper may be used in a plating process. The photoresist layer and other appropriate layers, such as the seed layer, can be removed leaving conductive studs 125 that provide for subsequent mechanical and electrical interconnection and a standoff with respect to active layer 20 and insulating layer 26 if present. In some instances, the conductive studs 125 include a height in a range of 10-100 micrometers (μm), 5-50 μm, or about 25 μm.

A conductive stud is a conductive interconnect structure that may have generally vertical sides and may be wider than it is tall, built-up on a substrate, such as over an active surface of a chip, polyimide, or mold compound. A conductive stud, though typically formed of the same materials as a pillar or post would be formed, may differ from a pillar or post, each of which may have a height greater than its width. A conductive stud, though it is commonly formed in a cylindrical shape, may be formed with a cross-sectional area that is circular, oval, octagonal, or as any polygonal or other shape and size. Another use for a conductive stud is as a dummy thermal conductive stud that is not electrically coupled to an active electrical circuit but is instead thermally coupled to a heat source of an active device to conduct and/or dissipate the heat to another structure, such as to a die pad on a surface of the component 14. The generally vertical sides of a conductive stud 125 are different from the sides shape that exists for a solder ball or a compressed or outwardly deformed solder ball that has generally rounded sides. The generally vertical nature of a conductive stud 125 comes from being formed in a structure that has been previously developed or etched, such as within openings in a photoresist layer, which will also be generally vertical, although it may comprise imperfections or irregularities in shape that result from the etching process, the photoresist material, or other materials and processes used. For example, developing or etching does not generally perfectly or uniformly remove the photoresist within the openings, and therefore forms imperfect, generally vertical openings for deposition of conductive materials for the conductive stud 125. The term “generally vertical” as used herein includes perfectly vertical and imperfectly vertical sides. A conductive stud is not a wire bond and is not solder.

FIG. 1C further illustrates an instance in which one or more of an optional adhesive or a die attach film (DAF) 41 or conductive material 30 may be attached to the back surface 18 of the component 14, such as for subsequent mounting on a carrier. FIG. 1C also illustrates wafer 10 can be singulated with a saw or wafer cutting tool 32 into individual components 14 through saw streets 16 using a saw blade, laser cutting tool, plasma, or a scribe and break process. In some instances, the components 14 will have a thickness (shown in the vertical direction, bottom to top, of the page) of between about 25 μm to about 150 μm for thin ground wafers, or about 100 μm to about 800 μm for thick ground wafers.

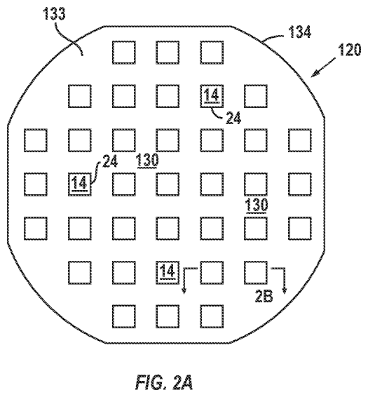

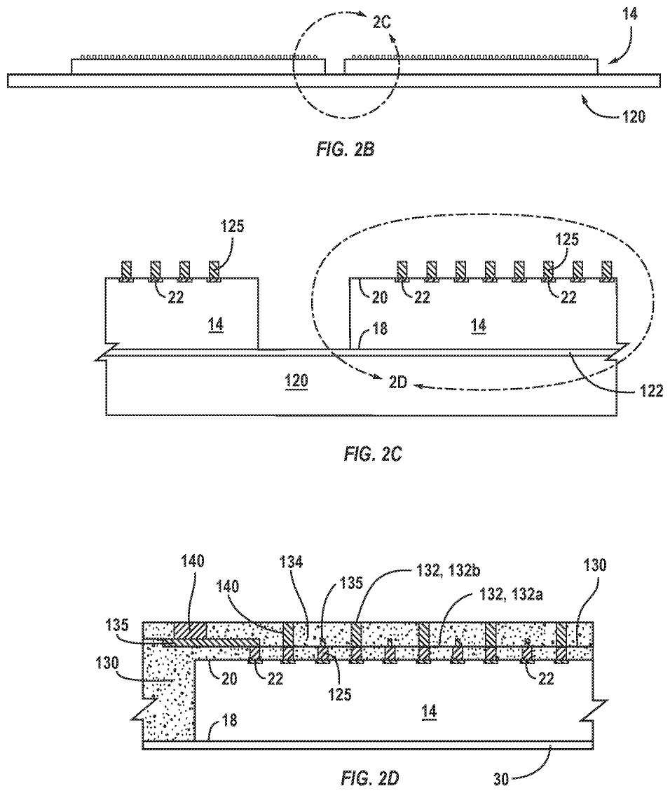

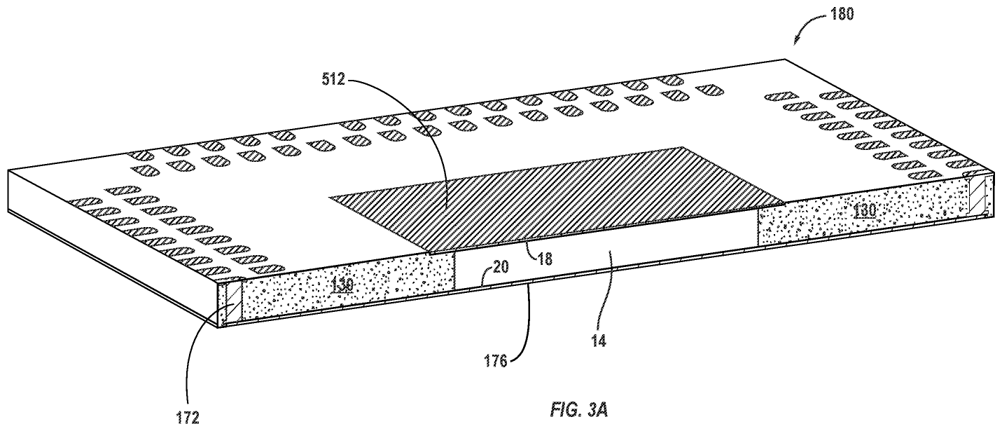

FIG. 2A illustrates a plan or top view of the temporary carrier 120, which may comprise a form factor or footprint of a wafer (circular footprint), a panel (square or rectangle), or of any suitable shape (such as generally circular with flat edges), and may comprise a diameter or width of 200-600 mm, such as 300 mm, or of any other suitable size. Components 14 may be disposed over temporary carrier 120 using a pick and place operation, or in any other suitable way. An encapsulant 130 can be deposited around the components 14, including over at least 5 sides of components 14, such as around 4 sides surfaces and over a surface or active layer 20 or over a backside 18 (as illustrated in FIG. 2C). The encapsulant 130 can be deposited around the plurality of components 14 using a paste printing, compression molding, transfer molding, liquid encapsulant molding, lamination, vacuum lamination, spin coating, or other suitable application method. The encapsulant 130 can be a polymer composite material, such as epoxy resin with filler commonly referred to as molding compound or EMC, epoxy acrylate with filler, ABF (Ajinomoto Build-up Film®), or other polymer with proper filler. Components 14 can be embedded together in encapsulant 130, which can be non-conductive and provide mechanical rigidity as well as environmentally protect the components 14 from external elements and contaminants.

The orientation of components 14, can be either face up with active layer 20 oriented away from carrier 120 to which the components 14 are mounted, or alternatively can be mounted face down with active layer 20 oriented toward the carrier 120 to which the components 14 are mounted. Accordingly, an adhesive 41 can be included or omitted from over back surface 18 of components 14, depending on the process used for encapsulating the components 14 and forming a panel or reconstituted panel 133 comprising components 14 fully molded within encapsulant 130.

The panel 133 can optionally undergo a curing process to cure encapsulant 130. A surface of encapsulant 130 can be substantially coplanar with adhesive 41. Alternatively, encapsulant 130 can be substantially coplanar with backside 18, the encapsulant being exposed by the removal of carrier and interface layer. The reconstituted panel 133 can include a footprint or form factor of any shape and size including circular, rectangular, or square, such as a form factor in a range of 200-600 millimeters (mm), including that of a semiconductor wafer including a circular footprint having a diameter of 300 mm. Any other desirable size can also be formed.

FIG. 2B illustrates a cross-sectional side view in which the components 14 (from FIG. 1C) are disposed face up over a temporary carrier 120, the component 14 comprising conductive studs 125 over a surface (such as the active layer 20) of the component 14. The component 14 may be placed adjacent one another, such as in a side-by-side arrangement, and subsequently coupled together. Multiple components 14 may also be processed together at a same time over the temporary carrier 120, such as shown and described with respect to FIG. 2A. It will be understood by a person of ordinary skill in the art (POSA), that the close-up views of just portions of the component 14 are shown as representing a small portion of what may be occurring at reconstituted wafer or panel level.

In some instances, the substrate or temporary carrier 120 may be a reusable carrier, a sacrificial carrier, or any suitable carrier that may be a metal carrier, a silicon carrier, a glass carrier, or a carrier made of other suitable material, which may further comprise a release layer. The temporary carrier 120 may be used for the molding or encapsulating process, and then be removed after the encapsulant, such as mold compound, epoxy mold compound (EMC), filled epoxy film such as ABF, or other dielectric such as polyimide has been placed, cured, or both, such that the encapsulant provides structural support and the temporary carrier is no longer needed for processing. The components 14 may be placed adjacent one another, such as in a side-by-side arrangement, so that multiple components 14 may be formed at a reconstituted wafer or panel level and processed through various fabrication steps, before being singulated into individual semiconductor assemblies. As such, multiple components 14 may also be processed together at a same time over the temporary carrier, which will be understood by the POSA, even when a close-up view of just portions of the components 14 are shown.

FIG. 2C illustrates a close-up view of the component 14 taken at section marker 2E of FIG. 2B, emphasizing the conductive studs 125 (which, e.g., may be formed of copper) may be formed over the active layer, and aligned on the components 14. The conductive studs 125 may vary in their orientation and arrangement according to a desired function or design, such as being disposed about a perimeter of the component 14, being formed in multiple rows across the component 14, or by being disposed in an array across the component 14. An optional interface layer 122, such as double-sided tape, film or deposited material, may be used beneath the components 14 to temporarily hold them to the temporary carrier 120 during processing.

FIG. 2D, continuing from FIGS. 2B and 2C, illustrates disposing an encapsulant 130 around the component 14 face-up over a temporary carrier 120 around four side surfaces of the component 14, over the active layer of the components 14, and around the conductive studs 125. As used herein, over, on or around may mean in direct contact with, or with other intervening layers, such as polymer or polyimide layers disposed between the components 14 and the encapsulant 130. The conductive studs 125 formed over the active layer of the components 14 may be in contact with, surrounded by, partially encircled by, or encapsulated or molded with a single encapsulant, polyimide or mold compound at a single step such that the same encapsulant, polyimide or mold compound 130 is disposed around the components 14. The encapsulant 130 can be deposited around the plurality of components 14 using a paste printing, compression molding, transfer molding, liquid encapsulation, dispensing, lamination, vacuum lamination, spin coating, slit or slot die coating, or other suitable application. The encapsulant 130 comprises an organic material, a mold compound, a polyimide, a composite material, such as epoxy resin with filler, such as ABF or epoxy acrylate with filler, and is a material suitable for planarizing, such as through chemical mechanical planarizing (CMP) or grinding. As such, in some instances the encapsulant 130 will not be a polymer material, such as an un-filled polyimide, that does not perform well in a grinding operation, and may gum-up a grinding wheel.

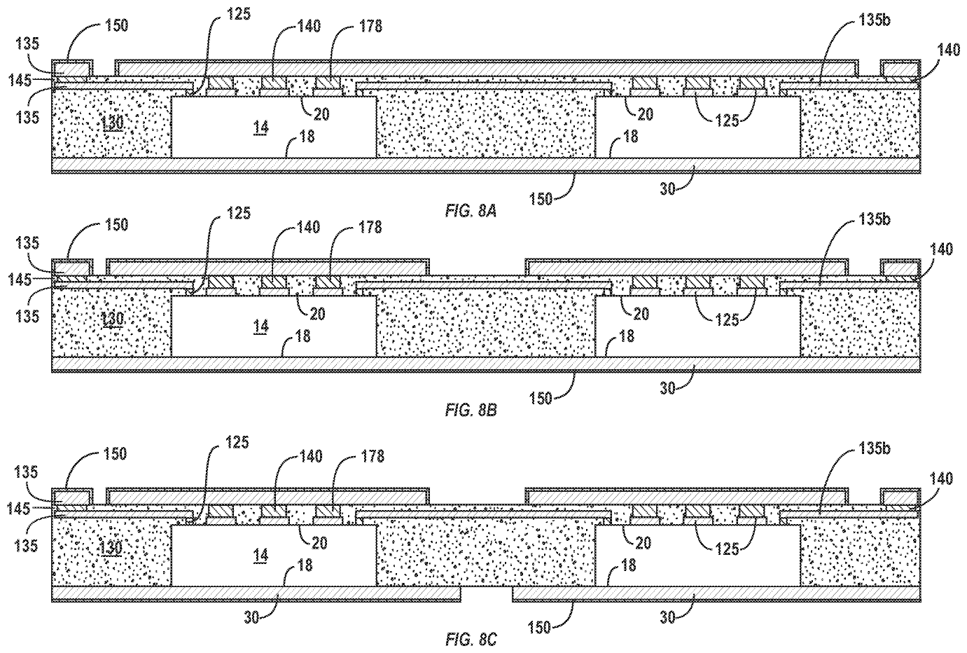

FIG. 2D, illustrates a cross-sectional side view of forming a first conductive layer 135 and conductive stumps or first vertical conductive contacts 140 over the semiconductor component 14 and the encapsulant 130. The processes described with respect to the cross-sectional view of FIG. 2D (and similar FIGs.) apply to semiconductor assemblies that comprise a single semiconductor component 14, or multiple semiconductor components 14 (as illustrated, e.g., in FIGS. 8A-8C). For convenience and ease of illustration, various views are illustrated with respect to a single semiconductor component 14, but as will be appreciated by a POSA, also apply to electronic assemblies comprising multiple semiconductor components 14.

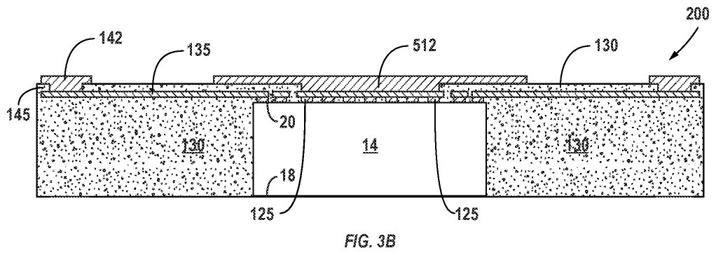

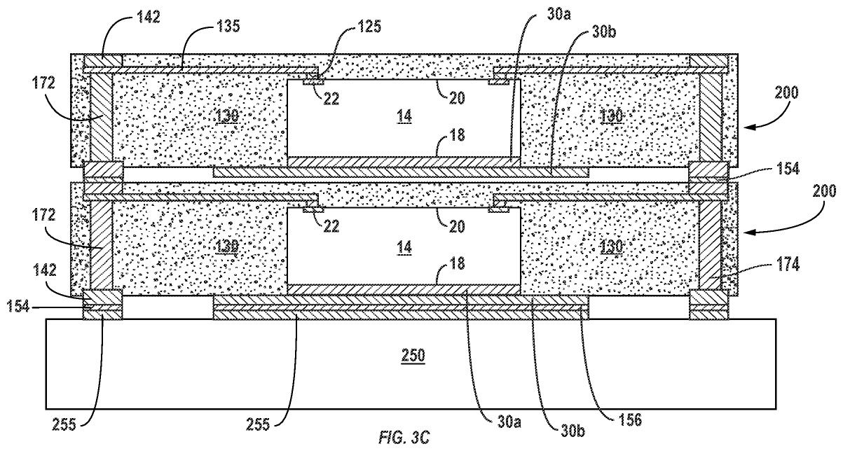

FIG. 2D also illustrates that after molding, the temporary carrier 120 may be removed, and a backside or back surface of the components 14 may be exposed from the encapsulant 130. Alternatively, a conductive backside material 30 may be disposed over a portion or all of the backside of the components 14 and a portion or all of the backside of the package encapsulant 130 as shown in FIG. 2D, and as discussed further with respect to FIGS. 3A-5C. The conductive backside material 30 may be electrically conductive, thermally conductive, or both. In some instances, the conductive backside material 30 comprises metal, such as copper or aluminum or any other one or more layers of metals. The conductive backside material may comprise a thickness in a range of 1,000 to 10,000 Angstroms (for thin applications) or 1-200 μm (for thicker applications). The conductive backside material 30 may also comprise diamond-like carbon (DLC), graphite, carbon nanotubes (CNTs), or other carbon material. One or more of a solderable metal system (SMS), an organic solderability preservative (OSP), or oxidation-resistant metal or metal alloy may be disposed over the conductive pads, flag, and backside material to resist oxidation over at least a portion of the conductive pads. Alternatively, a metal that does not readily oxidize, such as Ni, Ti, W, Cr, Ag, Au or Pd or a metal that has a thin self-limiting oxide thickness such as Al can be deposited over the thermally conductive backside material 30. The SMS or metal that does not readily oxidize may be formed by, electroplating, electroless plating, immersion plating, physical vapor deposition (PVD), or chemical vapor deposition (CVD) hot dipping or other deposition method of the conductive material over the conductive pads.

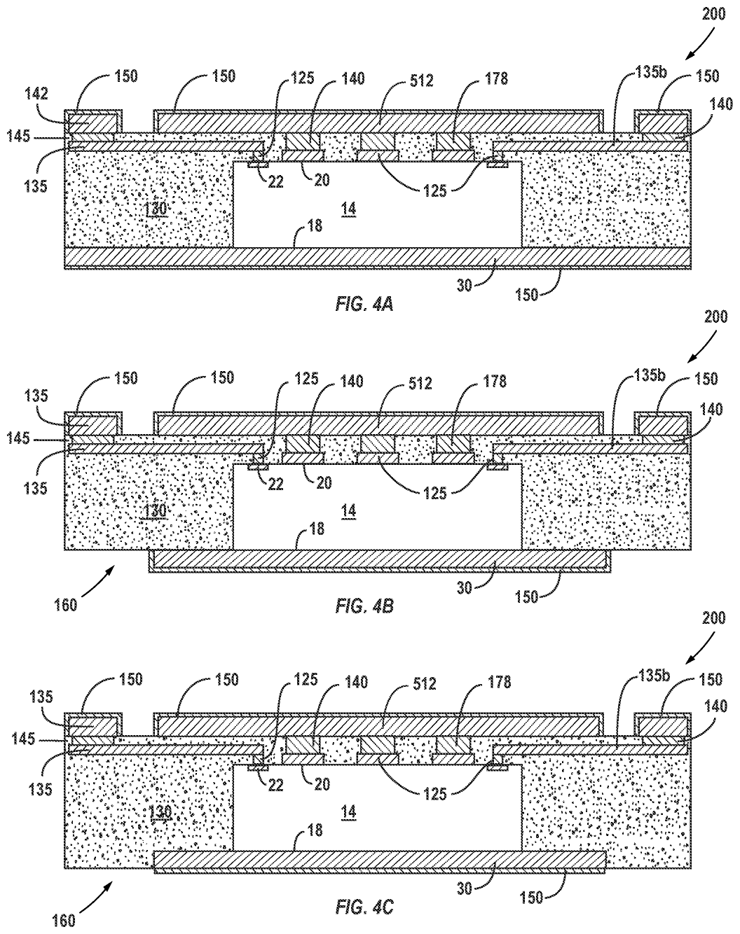

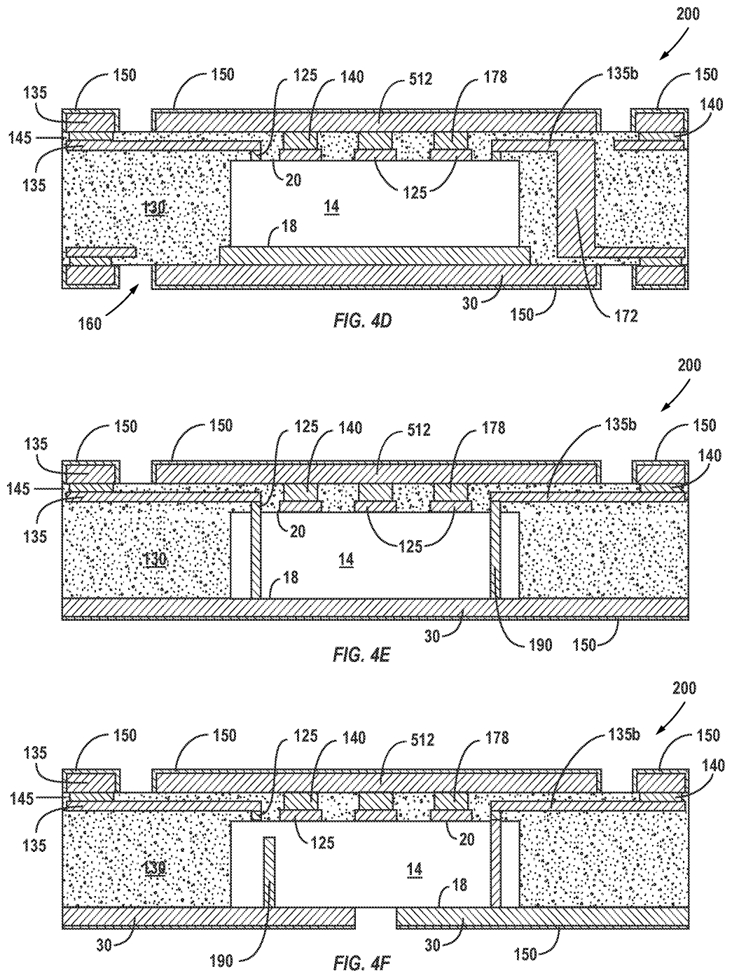

In some embodiments an electrical contact such as a metal via or a silicide region 190 is exposed on the backside of the chip. See, e.g., FIG. 4E. In other embodiments the backside of the chip is not sensitive to an electrically conductive material being present. In both of these cases a metallization process that deposits an electrically conductive metal directly on the chip backside and any contacts that are present may be used. A deposition typically begins with a barrier layer, an adhesion layer (or a single layer that serves both functions as a barrier and for adhesion may be used) that will adhere both to the chip backside and the encapsulant and may also serve as a barrier to ion migration into the chip substrate. Typical barrier and adhesion metals are Ti, TiN, Ta, TaN, W, Cr, V or alloys thereof deposited by a PVD process. The same PVD process can deposit a thin seed layer of conductive material such as Cu. After the barrier and adhesion layer deposition (and seed layer deposition if there is one) a relatively thick layer of the thermally conductive material can be deposited—such as by electroplating, electroless plating, PVD, CVD, or other suitable process.

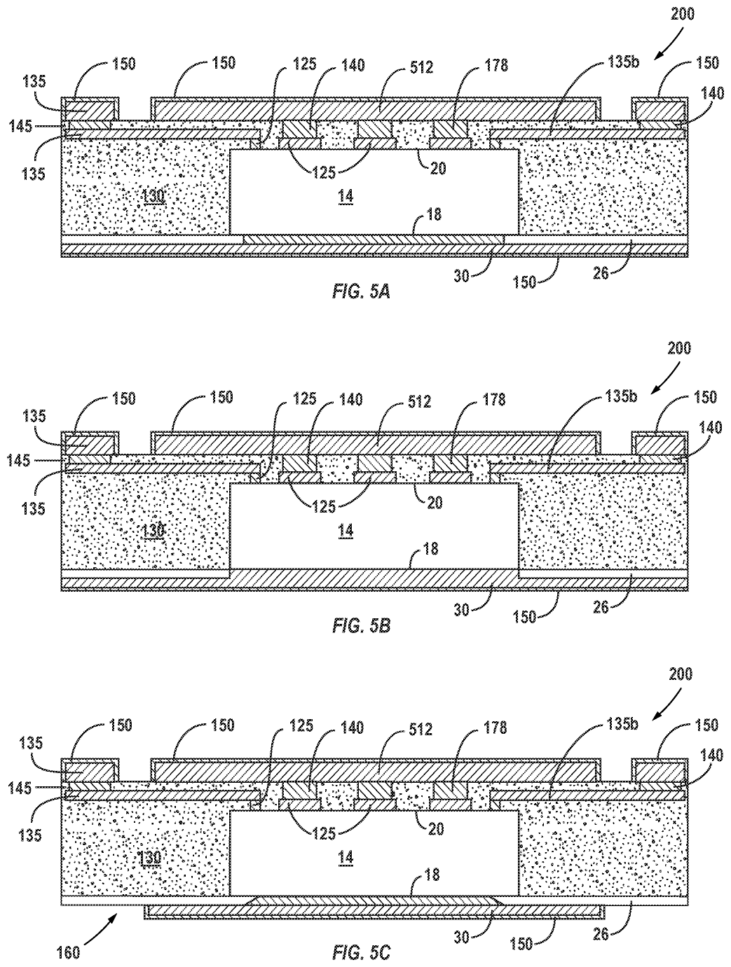

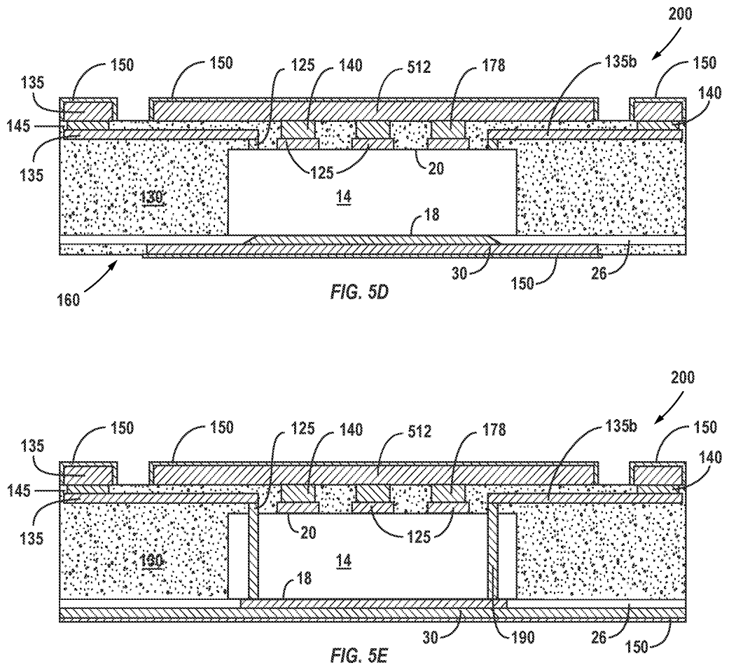

In some embodiments it is desirable to have the chip backside electrically isolated from the thermally conductive backside material 30 (as shown in FIGS. 5A-5C below), wherein an insulating layer may be formed or disposed before the thermally conductive backside material 30 is deposited. The insulating layer may be polyimide or other type of polymer (which may be spun on or otherwise deposited). The insulating material may be an inorganic dielectric that could be thinner than a polymer and also have a higher thermal conductivity—such as silicon oxide, silicon nitride, an oyxnitride, an SiOC material or the like deposited in a CVD-type process. A number of variations of the CVD process may be used, such as plasma-enhanced, ultra-high vacuum, inductively-coupled plasma, or other that all help to achieve a low deposition temperature that is compatible with the encapsulant 130. Another option for the insulator is a spin-on glass (SOG) or a vacuum-deposited polymer. Once such an insulator is deposited then the formation of the thermally conductive backside material 30 can proceed in a similar fashion as described previously.

As previously mentioned, the thermally conductive backside material 30 may comprise diamond-like carbon (DLC), graphite, or carbon nanotubes (CNTs) or other carbon-based material. Alternately the thermally conductive backside material 30 may comprise a metal. The carbon-based materials can be deposited by CVD processes, sol-gel processes or other deposition processes. The metal materials can be deposited by electroplating, electroless plating, immersion plating, PVD, or other method.

Planarizing or grinding the encapsulant 130 over the active surface to expose the conductive studs 125 may occur before or after removing the temporary carrier 120. As referenced above, FIG. 2D also illustrates a close-up view of a portion of a semiconductor chip or component 40 after planarizing the encapsulant over an active layer of the components 40 to create a substantially planar surface comprising exposed ends of the conductive studs and planarized encapsulant surface. In some instances, portions of, or residue from, the conductive material of the conductive studs 125 can be mixed with, deposited on, or spread across the first layer of encapsulant 130. In such instances, an etching process may be performed to remove the residue. The etching process may also recess the exposed ends 126 of the conductive studs 125 to create new lower exposed ends 126 that are recessed below the planar surface 131 of the first encapsulant layer 130 by a distance of 10 μm or less, 5 μm or less, 2 μm or less, or 1 μm or less. Thus, the substantially planar surface 132 may comprise the planar surface 131 of the encapsulant 130 offset from the recessed exposed ends 126 of the conductive interconnects 125.

The planarizing or grinding of the encapsulant produces a flatness comprising a total roughness height from peak to valley measurement of less 500 nanometers (nm), less than 350 nm, less than 250 nm, less than 200 nm, or less than 100 nm over a characteristic measurement distance. The characteristic measurement distance is defined by the ISO 4288 standard, an entirety of which is hereby incorporated by reference. The characteristic measurement distance may also be a distance great enough to characterize the roughness, such as to a generally accepted level of certainty, and in some instances could be a distance of three times the distance of the roughness. While conventional encapsulant grinding might be done with less flatness, greater accuracy and precision can be obtained by using integrated sensors such as laser, acoustic, or other non-contact methods to control the grinding resulting in better flatness. In some instances, the first conductive studs may be formed with a height of less than or equal to about 50 micrometers (μm) or less than or equal to about 250 μm, and then be ground down to a height of less than its original height, such as, in a particular embodiment, less than or equal to about 4 μm or 1 μm. As used herein, “about” or “substantially” means a percent difference less than or equal to 50% difference, 40% difference, 30% difference, 20% difference, 10% difference, or 5% difference. The exposed ends 126 of the conductive studs 125 may be coplanar, substantially planar, or flat with the planar surface 131 of the encapsulant 130, such as after the grinding with grinder 29. In some instances, portions of, or residue from, the conductive material of the conductive studs 125 can be mixed with, deposited on, or spread across the first layer of encapsulant 130. In such instances, an etching process may be performed to remove the residue. The etching process may also recess the exposed ends 126 of the conductive studs 125 to created new lower exposed ends 126 that are recessed below the planar surface 131 of the first encapsulant layer 130 by a distance of 10 μm or less, 5 μm or less, 2 μm or less, or 1 μm or less. Thus, the substantially planar surface 132 may comprise the planar surface 131 of the encapsulant 130 offset from the recessed exposed ends 126 of the conductive interconnects 125. In some embodiments the grinding and etching process may be combined in what is known as a Chemical Mechanical Polishing or CMP process.

FIG. 2D also shows a second encapsulant layer 134 over the encapsulant 130, such as on the planar surface 132, and further comprising the conductive layer 135 with its first conductive stumps 140 formed within photoresist layer openings. The conductive layer 135 may also include a redistribution layer (RDL) with RDL structures or traces 135b added through known methods similar to adding the conductive studs 125 and the first conductive stumps 140 through openings in a layer of photoresist. In other embodiments, additional RDL traces 135b may be included in any number of additional conductive layers formed over or below the conductive layer 135 using the same or modified methods of applying an RDL 135a as described herein. The respective first conductive layer 135 and first conductive stumps 140 may be configured to be electrically coupled with the conductive studs 125 of the components 14. Additionally, the first conductive stumps 140 may be formed similar to conductive studs 125. Additional conductive stumps 140 may be formed elsewhere in the structure within intermediate layers of encapsulant. The conductive stumps 140 may be planarized, undergo CMP, or be grinded with the encapsulant layer to create a planar or substantially planar surface layer that includes encapsulant and exposed conductive stumps 140. In some instances, a slight recess for the tops of the studs 126 may be present, such as from a result of an etching process.

In some embodiments, the grinding process may cause some smearing of portions of the conductive studs 125, conductive stumps 140, or conductive layer 135 across a portion of the planarized surface. The smeared conductive material can be removed by etching. As a result of the etching, the conductive studs 125 (and conductive stumps 140) may be recessed below the planar surface by about 1-1000 nanometers (nm), or 100-500 nm, or 200-300 nm.

The respective first conductive layers 135 and first conductive stumps 140 for each component 14 (like conductive studs 125) may be formed using one or more of PVD, CVD, electrolytic plating, electroless plating process, or other suitable metal deposition process. The first conductive layers 135 and first conductive stumps 140 may comprise one or more layers of copper (Cu), titanium (Ti) aluminum (Al), tin (Sn), nickel (Ni), gold (Au), silver (Ag), platinum (Pt), tungsten (W), tantalum (Ta), cobalt (Co) or other suitable electrically conductive material including alloys. As each conductive layer and structure is formed, additional encapsulant 130 may also be added to surround the structures.

Conductive stumps 140 are conductive interconnect structures that may have generally vertical sides and be wider than tall. A conductive stump may differ from a pillar or post, each of which may have a height greater than its width. A conductive stump may comprise a cylindrical shape and may further be formed in any polygonal or other shape and size. A conductive stump 140 may be used for electrical interconnect, signal transmission, power, ground, or as a dummy thermal conductive stump that is not electrically coupled to an active electrical circuit but is instead thermally coupled to a heat source of an active device to conduct and/or dissipate the heat to another structure, such as to a die pad on a surface of the component 14. The generally vertical sides of a conductive stumps 140 are different from the sides shape that exists for a solder ball or a compressed or outwardly deformed solder ball that has generally rounded sides. The generally vertical nature of a conductive stump 140 comes from being formed in a structure that has been previously developed or etched, such as within openings in a photoresist layer, which will also be generally vertical. Sides of the conductive stump 140 may comprise imperfections or irregularities in shape that result from the etching process, the photoresist material, or other materials and processes used. For example, developing or etching does not generally perfectly or uniformly remove the photoresist within the openings, and therefore forms imperfect, generally vertical openings for deposition of the conductive stump 140. The term “generally vertical” as used herein includes perfectly vertical and imperfectly vertical sides or sides that are about or substantially vertical. A conductive stump 140 is not a wire bond and is not solder.

Continuing with FIG. 2D, the first conductive layer 135 and first conductive stumps 140 are shown formed over the encapsulant 130, such as on the planar surface 132, and configured to be electrically coupled with the conductive stumps 125 of the semiconductor component 14. The first conductive layer 135 can be formed as one or more structures or as an RDL 135a comprising a trace line and space of less than or equal to 2 μm for a pitch of less than or equal to 4 μm, or in other instances comprising line and space of less than or equal to 5 μm for a pitch of less than or equal to 10 μm. Lager pitches and less dense connections are also possible. The first conductive layer 135 or structures may also be formed so as to directly contact the encapsulant 130 and the conductive stumps 125 without capture pads.

The first conductive stumps 140 may also be formed at a same time as the first conductive layer 135 (such as with a single plating process) or at a second time after the forming of the conductive layer 135 (such as with a dual plating process, also referred to as a two-plate process). In both the single plating process, and the dual plating process, a seed layer may be formed. The seed layer may be of Ti followed by Cu, TiW followed by Cu, or a coupling agent followed by Cu. The seed layer may be deposited by sputtering, electroless plating, or by depositing laminated Cu foil combined with electroless plating. In some embodiments, the seed layer may additionally comprise a wetting layer, a barrier layer, and/or an adhesive layer bonded to the encapsulant 130, the conductive layer 135, or both.

FIGS. 3A and 3B illustrate various views of QFNs without leadframes similar to those described above formed according to the processes discussed herein. Each figure illustrates how the technology and processes described and illustrated in relation to this disclosure can be combined with other various technologies for use in assembly or semiconductor packaging. Those of ordinary skill in the art will understand how to combine the disclosures below with the processes described above based on the disclosures provided herein.

Although the illustrations show QFN packages, the technologies and processes disclosed herein can also be used with DFN and SON packages, or with LGA packages with an array of bond pads disposed on the surface of the package, or with packages that are not “no-lead” packages—such as BGA packages. For ease of description, “QFN” is used as a non-limiting term that includes all of the other packages and assemblies referenced herein. FIG. 3A illustrates a perspective view of an embodiment of a QFN package or assembly 180 with a cross-section through a center of the package. The QFN package 180 includes including at least one through mold post (TMP) 172 extending from a conductive pad on a first surface of the package to an opposing side of the package 170, providing vertical interconnect through the package, passive devices, or both. In some instances, the land routing or land layout of the present package may be a mirror image of a traditional QFN, DFN or SON that uses wire bonding. If desired, additional routing could be used to mitigate the difference. In some embodiments, the electronic assembly comprises a through mold post 172 or conductive interconnect between a top and bottom conductive flag or conductive layer 176.

FIG. 3B illustrates a QFN package structure formed like the QFN package 180 of FIG. 3A, but showing additional detail that is present in some embodiments. Additional connecting detail between the component 14 and the conductive pads 142 includes encapsulant 130 and dummy thermal conductive stumps 178. The exposed thermally conductive pad, die pad, or flag 512 may be formed as a thicker layer of material to more efficiently transfer heat laterally. The plurality of dummy thermal conductive stumps 178 are shown extending directly to the component 14 or conductive studs 125 of the component 14 to allow the exposed thermally conductive pad, die pad, or flag 512 to improve heat transfer out of the QFN package 180.

FIG. 3C illustrates QFN, DFN, or SON packages 184, that may also comprise other desired assemblies, such as where the components 14 are without an active layer, the component 14 further comprising a Micro-Electro-Mechanical Systems (MEMS), an optical component, an IPD, a bridge die, an embedded device, or other suitable component. The packages or assemblies 184 are stacked on top of each other and mounted to a printed circuit board (PCB) 250 with a surface mount interface. TMPs 172 are formed within the chip packages 184 to conduct signals between the chip packages 184 and the PCB 250. In some embodiments, the TMPs 172 of different QFN, DFN or SON packages are connected to each other or to the conductive pads 255, such as with solder 154. In some embodiments, an additional conductive pad 142 connects TMPs 172 with the conductive pad 255 that contacts the PCB 250.

A solderable metal system (SMS) 154 can be formed over at least a portion of the conductive pad 142. In some embodiments, organic solderability preservative (OSP) may be used instead of or in addition to an SMS to enhance solderability of the conductive pads 142 and to resist oxidation over at least a portion of the conductive pads 142. The SMS 154 may comprise a nickel layer 1-2 μm thick, followed by a layer of palladium (Pd) 0.1-0.05 μm thick. Any suitable material may comprise the SMS 154, including one or more layers of Ni, Pd, gold (Au), tin (Sn), solder, silver (Ag), OSP, or other suitable material, forming the SMS as a single or multi-material build-up. The SMS 154 may be formed over a top surface and 4 (or any number) of adjoining side surfaces of the conductive pad 142. As used herein, the “sides” of the conductive pads 142 may be any adjoining or adjacent surface, including vertical, sloped, chamfered, or other surfaces. The conductive pads 142 and SMS 154 may also be offset from, or formed over, the encapsulant 130 or mold compound. A TIM 156 may reside between the PCB 250 and the second backside material 30b on the QFN, DFN, or SON package 184 that resides immediately above the QFN, DFN, or SON package 184.

In certain embodiments, component 14 contacts a first backside material 30a which contacts a second backside material 30b. Other features may include encapsulant 130 surrounding the component 14, TMPs 172, conductive studs 125, conductive layers 135, the first conductive pad 30a, and associated components.

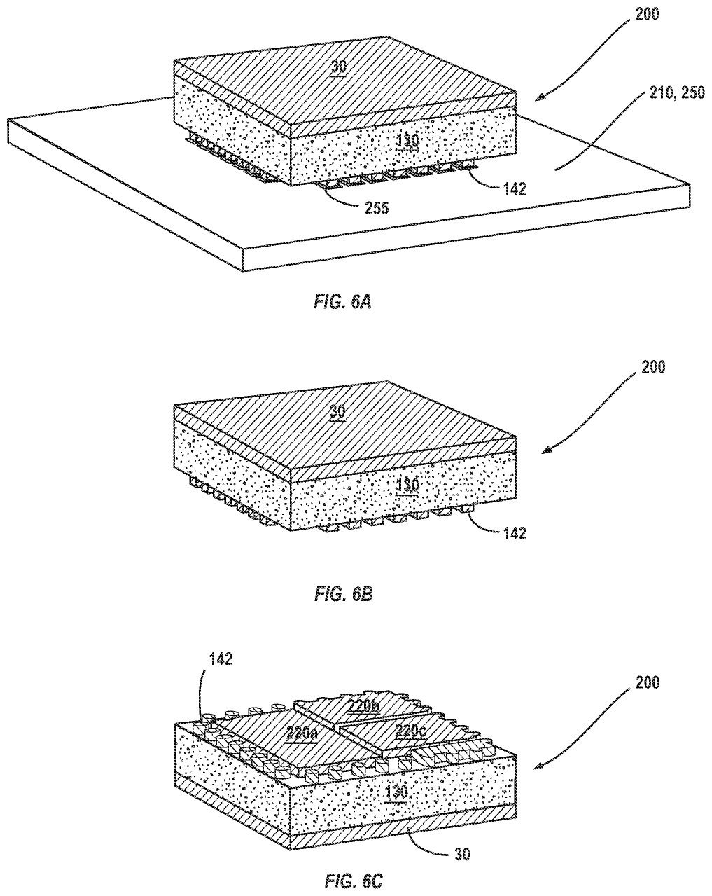

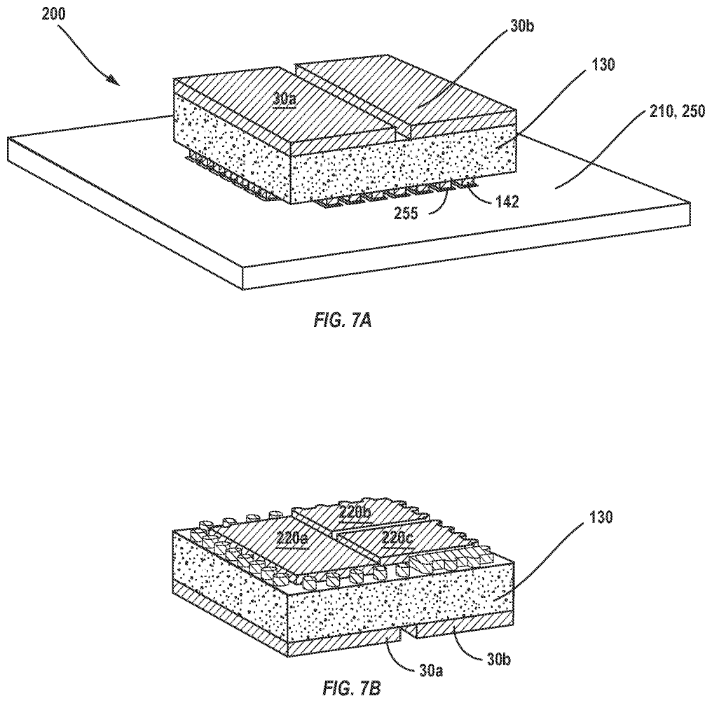

FIGS. 4A-4F illustrate examples of assemblies, semiconductor assemblies, QFN packages, LGA packages, or other suitable applications, in which a thermally conductive backside material may be included or used. FIGS. 4A-4F provide cross-sectional side views while other FIGs., such as FIGS. 6A-7B, illustrate isometric views of the assemblies. As illustrated in FIGS. 4A-4F, the thermally conductive backside material extends across a backside of the semiconductor chip and a backside of the encapsulant. The FIGs. also illustrate the electronic assembly may comprise conductive pads, wherein the conductive pads comprise one or more of an input electrical contact, an output electrical contact, an IO contact, a power contact, a ground contact, a combinational IO pad (for one or more of an input signal, an output signal, a ground, and a power) a clock contact, electrical contacts, a bump, a solder ball, a solder bump, a BGA, a LGA, land pads, copper pillars, and copper pillars with solder, to couple with devices outside the electronic assembly.

FIG. 4A illustrates an instance in which the thermally conductive backside material is coupled to, and may directly contact, the backside of the component 14. The thermally conductive backside material 30 may extend to an edge of the semiconductor (or electronic) assembly 200, and can be sawn, separated, or singulated during formation of individual assemblies 200, such as during singulation or separation of the reconstituted or embedded panel or wafer. Further, FIGS. 4A-5E also illustrate instances in which the component 14 backside material may be thermally conductive, electrically conductive, or both. In this case the thermally (and electrically) conductive material 30 can be deposited directly on the backside of the component 14 as shown, without an insulating or other layer sandwiched or disposed therebetween the component 14 and the conductive material 30.

FIG. 4A further illustrates the thermally conductive backside material 30 may comprise an organic solderability preservative (OSP) or SMS 150 formed thereon. The OSP or SMS 150 may also be formed on or over conductive pads 142 and any exposed surface at a periphery of the assembly 200.

As further illustrated in FIG. 4A, one or more of electrical conductivity, signal routing, and thermal transfer with respect to the component 14 may pass through conductive pad or contact pads 22, conductive studs 125, RDL traces 135b, conductive stumps 140, and conductive pads 142. Conductive studs 125 contacts dummy thermal conductive stumps 178 that contact exposed thermally conductive pad, die pad, or flag 512.

FIG. 4B illustrates an instance in which the thermally conductive backside material 30 further comprises a pull back 160 from an edge 202 of the electronic assembly, and the backside material 30 is formed over (or after) the encapsulant 130 is formed around the component 14.

FIG. 4C illustrates an instance in which the conductive backside material 30 also comprises a pull back 160 from an edge of the electronic assembly 200, and the backside material is formed over, and is at least partially embedded within, the encapsulant 130. The conductive backside material 30 may be formed by first placing the backside material 30 onto the temporary carrier 120, then placing or mounting the component 14 on the backside material 30, after which the component 14 and the conductive backside material 30 are molded together with encapsulant 130 being disposed around both. In another embodiment, the component 14 may be placed or mounted on the backside material 30 before the component is placed or mounted on the temporary carrier 120, and subsequently the jointed of assembly of both the component 14 and backside material 30 may together be disponed on the temporary carrier 120, after which the component 14 and the conductive backside material 30 are together encapsulated or molded with encapsulant 130. The backside material 130 may be both a thermal conductor and a material that helps to bridge the low coefficient of thermal expansion (CTE) of the component 14 and the higher CTE of the PCB to which the package 200 is mounted. In some instances, a DBC (Direct Bond Copper) material—alumina ceramic with copper bonded on both sides may be used for the backside material 30. In some instances, the component 14 may be mounted to the backside material 30 with a high thermal conductivity material—such as a die attach material highly loaded with thermally conductive filler, a sintered material such as silver, or a solder.

FIG. 4D illustrates an instance in which the electronic assembly 200 is formed with a package on package (POP) arrangement, similar to what was shown in FIGS. 3A and 3B. FIG. 4D illustrates an example wherein at least a portion of the thermally conductive backside material 30 is configured to be electrically connected to the semiconductor chip 14. In some instances, the electronic assembly 200 may further comprise a through mold electrical interconnect or post 172 coupled with the active layer 20 and extending to the backside of the electronic assembly 200.

FIGS. 4E and 4F illustrate instances in which the electronic assembly 200 may further comprise a via 190 formed within the semiconductor chip or embedded device 14, the via 190 being coupled with, or extending through, the active layer 20 and extending to the back surface 18 of the semiconductor chip 14. The conductive backside material 30 can then be coupled with the via 190.

The electrical connection with the conductive backside material 30 can also be facilitated by a diffusion and a silicide contact (or a similar contact) 190 within the chip 14, which is coupled with the active layer 20, and further extend to the backside 18 of the chip 14, as illustrated in FIGS. 4E and 4F. In some instances, the via or diffusion 190 will couple with a backside of the active region 20, as illustrated on the left of FIG. 4F. In other instances, the via 190 will couple with a frontside conductive stud 125, conductive layer 135, RDL trace 135b, or other feature, having passed through the active layer or active area, as illustrated on the right of FIG. 4F. Vias 190 may be used for power connections, ground connections, and signal connections or transmission.

FIGS. 5A-5F illustrate structures similar to those shown in FIGS. 4A-4F, but with an electrical insulator or insulating layer 26 disposed between the backside 18 of the component or semiconductor chip 14 and the thermally conductive backside material 30. More specifically, FIGS. 5A-5F illustrate the insulating layer 26 disposed between the backside of the semiconductor chip and the thermally conductive backside material 30, wherein the insulating layer 26 comprises a layer of polyimide, polymer, inorganic dielectric, or other suitable material. FIGS. 5A and 5B illustrate both the insulating layer 26 and the thermally (and electrically) conductive backside material 30 extending to a package or assembly edge 202. The insulating layer 26 extends to the package edge 202 to insulate the embedded device or component 14 from interference from the electrically conductive backside material 30. When the insulating layer 26 is disposed between the encapsulant (EMC) 130 and the semiconductor chip or embedded component 14, an opening or void in or through the insulating layer will allow the conductive backside material 30 to electrically connects to the exposed contact or via 190 at the backside of the embedded component 14.

FIG. 5C illustrates an arrangement similar to FIG. 4B with a pull back 160 for the thermally (and electrically) conductive backside material 30, and similar to FIG. 5A with the insulating layer 26 extending to the package edge 202.

FIG. 5D illustrates an arrangement similar to FIG. 4C with a pull back 160 for the thermally (and electrically) conductive backside material 30, which is disposed within and not just over the encapsulant 130. FIG. 5D is also similar to FIGS. 5A-5C in that the insulating layer 26 extends to the package edge 202.

FIG. 5E illustrates an arrangement similar to FIG. 4E by illustrating instances in which the electronic assembly 200 may further comprise a via 190 formed within the semiconductor chip or embedded device 14. FIG. 5E differs from FIG. 4E by the inclusion of the insulating or passivating material 26 disposed between the backside 18 of the component 14 and thermally conductive material 30.

FIG. 6A illustrates an isometric view of an assembly or semiconductor assembly 200 (which may comprise one or more components 14 disposed therein) mounted to a substrate 210 or PCB 250. The semiconductor assembly 200 may comprise conductive backside material disposed at the topside of the mounted assembly. As described herein, the conductive backside material 30 may be thermally conductive, electrically conductive, or both thermally and electrically conductive. The bottom portion of FIG. 6A shows conductive pads 142 coupled to conductive pads 255 of the PCB 250.

FIG. 6B illustrates an isometric view of the assembly or semiconductor assembly 200, similar to what was shown in FIG. 6A. FIG. 6A differs from FIG. 6A by omitting the substrate 210 or PCB 250.

FIG. 6C illustrates an isometric view of the semiconductor assembly 200 from the reverse (upside down) view of what was shown in FIGS. 6A and 6B. FIG. 6C illustrates a frontside of the assembly 200 oriented upwards to display multiple thermal and electrical frontside conductive pads 220 and single backside thermally conductive material 30 displayed at the bottom or lower portion of the FIG. 6C opposite the conductive pads 220.

FIG. 7A illustrates an isometric view of an assembly or semiconductor assembly 200 (which may comprise one or more components 14) mounted to a substrate 210 or PCB 250, similar to that shown in FIG. 6A. FIG. 7A differs from FIG. 6A by showing more than one conductive backside material 30 at the topside of the mounted assembly 200, wherein the conductive backside material 30 is thermally conductive, or thermally and electrically conductive. FIG. 7A further shows conductive pads 142 coupled to conductive pads 255 of the substrate 210 or PCB 250.

FIG. 7B (similar to FIG. 6C) illustrates an isometric view of the assembly 200 from the reverse (upside down) view of what was shown in FIG. 7A, with a frontside of the semiconductor assembly 200 oriented upwards to display multiple thermal and electrical frontside conductive pads 220 (including 220a, 220b, and 220c) and multiple segments or portions of backside thermally conductive material 30 (including 30a and 30b) displayed at the bottom or lower portion of FIG. 7B.

FIGS. 8A-8C illustrate various cross-sectional views of assemblies or semiconductor assemblies 200 similar to those shown in FIGS. 4A-5E, but further include more than one component 14 within the assembly. A POSA will appreciate that any of the features shown in the other FIGs. (such as the insulating layer 26 or vias 190) may also be included in the multi-component assemblies 200 shown in FIGS. 8A-8C. FIG. 8A illustrates a cross-sectional profile view of a multi-component assembly 200 comprising a single or shared conductive backside material 30, and a shared frontside conductive material 220, 512.

FIG. 8B illustrates another cross-sectional view of an assembly 200 similar to that shown in FIG. 8A. FIG. 8B differs from FIG. 8A by comprising multiple separate or isolated (not shared) conductive frontside materials 220, 512 disposed over the components 14.

FIG. 8C illustrates another cross-sectional view of an assembly 200 similar to that shown in FIG. 8B. FIG. 8C differs from FIG. 8B by comprising multiple separate or isolated (not shared) backside materials 30 disposed over the components 14.

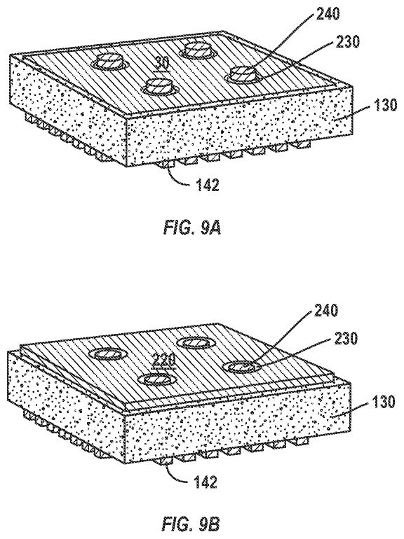

FIGS. 9A and 9B illustrate the thermally conductive backside material 30 (whether formed as one or more than one portion or segment) may be patterned to provide a first portion of material that is configured to be electrically coupled with the component 14 and a second portion of material that is electrically isolated from the component 14. FIGS. 9A and 9B illustrate the first portion of material is configured as an island that is electrically coupled with the component 14 and electrically separated from the second portion of material by a moat 230, wherein the second portion of material comprises a thermal pad larger than the island 240. In some instances, the islands 240 may be formed as circles or dots, or of any other suitable geometric or organic shape.

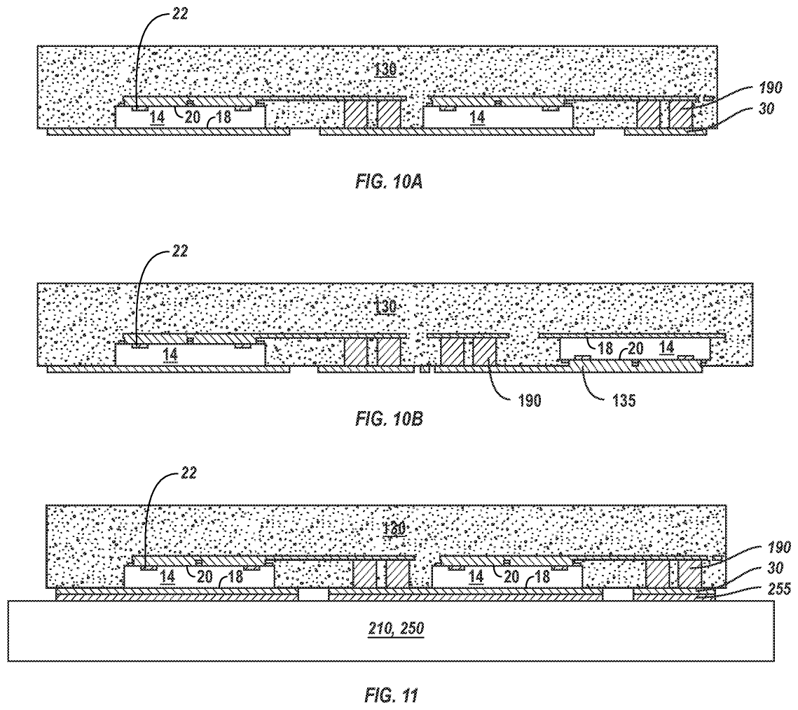

FIG. 10A shows two components 14 mounted face up within the assembly 200. FIG. 10B illustrates an instance in which the electronic assembly 200 comprises at least one component 14 face up and at least one component 14 face down within the assembly 200. FIGS. 10A and 10B further illustrate conductive pads 22 on component 14 coupled with conductive layer 135, vias

FIG. 11, similar to FIGS. 10A and 10B, illustrates an example of the component 200 is coupled to substrate 210 or PCB 250.

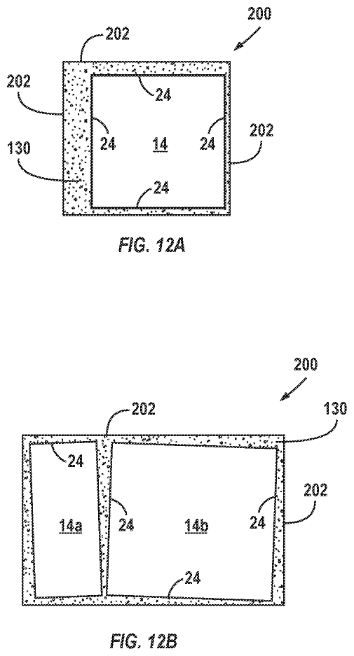

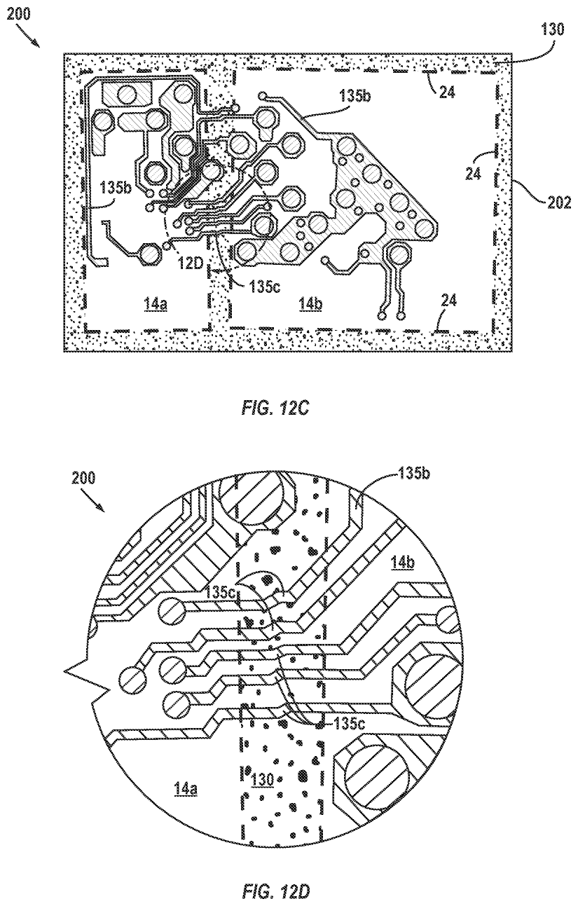

FIGS. 12A-12D provide various illustrations of assemblies 200, in which unit specific patterning or adaptive patterning may be used. FIG. 12A provides a plan view of a component 14 disposed within the encapsulant 130 in such a way that die shift, die rotation, or both, are present within the assembly. In other words, the component 14 is offset, rather than centered, with respect to the edges 202 of the assembly 20. More specifically, component 14 is disposed inside of the encapsulant 130, and is offset to the right and slightly down so that it is not equidistantly positioned with respect to the edges 202 of the assembly 200.

FIG. 12B provides a plan view of more than one component 14 (e.g., components 14a, 14b) disposed within the encapsulant 130 in such a way that die shift, die rotation, or both, are present within the assembly 200. FIG. 12C is a cut away view of the assembly 200 shown in FIG. 12B and shows features of the conductive layer 135, including the RDL traces 135b inside the encapsulant 130. FIG. 12D presents a blowup or enlarged portion of FIG. 12C taken along the section line 12C. FIG. 12D shows how unit specific patterning can create jogs or adjustments 135c in the conductive RDL traces 135b (and other parts of the conductive layer 135 and other features within assembly 200).

While this disclosure includes a number of embodiments in different forms, the particular embodiments presented are with the understanding that the present disclosure is to be considered as an exemplification of the principles of the disclosed structures, devices, methods, and systems, and is not intended to limit the broad aspect of the disclosed concepts to the embodiments illustrated. Additionally, it should be understood by those of ordinary skill in the art that other structures, manufacturing devices, and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art. As such, it will be evident that various modifications and changes may be made thereto without departing from the broader spirit and scope of the inventions as set forth in the appended claims. The specification and drawings are, accordingly, to be regarded in an illustrative sense rather than a restrictive sense.

What is claimed is:

1. An electronic assembly, comprising a quad flat no-lead (QFN), dual flat no-lead (DFN) or small outline no-lead (SON) package, an LGA package, or a BGA package without a leadframe, comprising:
a semiconductor chip comprising conductive studs over an active layer of the semiconductor chip;
a first encapsulant disposed as a single layer of material around four side surfaces of the semiconductor chip, over the active layer of the semiconductor chip, and around at least a portion of sidewalls of the conductive studs;
a thermally conductive backside material disposed over a backside of the semiconductor chip;
a substantially planar surface disposed over the active layer of the semiconductor chip, wherein the substantially planar surface comprises ends of the conductive studs and a planar surface of the first encapsulant, wherein the planar surface of the first encapsulant comprises a roughness less than 500 nanometers (nm) over a characteristic measurement distance;
conductive structures disposed over the planar surface and configured to be electrically coupled with the semiconductor chip;
a second encapsulant disposed over the conductive structures; and
conductive pads disposed over the second encapsulant in the form of contact pads.

2. The electronic assembly of claim 1, wherein the thermally conductive backside material comprises metal.

3. The electronic assembly of claim 2, wherein the thermally conductive backside material comprises copper with a thickness in a range of 1,000 angstroms to 200 μm.

4. The electronic assembly of claim 2, wherein the thermally conductive backside material extends across a backside of the semiconductor chip and a backside of the encapsulant.

5. The electronic assembly of claim 4, wherein the thermally conductive backside material extends to an edge of the electronic assembly.

6. The electronic assembly of claim 4, wherein the thermally conductive backside material further comprises a pull back from an edge of the electronic assembly.

7. The electronic assembly of claim 1, wherein the thermally conductive backside material is electrically isolated from the semiconductor chip.

8. The electronic assembly of claim 1, wherein the thermally conductive backside material is configured to be electrically connected to the semiconductor chip.

9. The electronic assembly of claim 8, further comprising a via or a diffusion with a silicide contact coupled with the active layer and extending to the backside of the semiconductor chip.

10. The electronic assembly of claim 1, wherein the thermally conductive backside material is patterned to provide a first portion of material that is configured to be electrically coupled with the component and a second portion of material that is electrically isolated from the component.

11. The electronic assembly of claim 1, further comprising a semiconductor chip, a Micro-Electro-Mechanical Systems (MEMS), an optical component, an IPD, an active or passive bridge die, an interposer, or an embedded device.

12. The electronic assembly of claim 1, wherein the conductive pads comprise one or more of an input electrical contact, an output electrical contact, an TO contact, a power contact, a ground contact, a source contact, a clock contact, a drain, a gate, an emitter, a collector, a base, a cathode, an anode, electrical contacts, a bump, a solder ball, a solder bump, a BGA, a LGA, land pads, copper pillars, and copper pillars with solder, to couple with devices outside the electronic assembly.

13. The electronic assembly of claim 1, wherein the electronic assembly is formed without exposed copper.

14. The electronic assembly of claim 13, further comprising a plurality of dummy thermal conductive studs disposed over the active layer of the semiconductor chip and thermally coupling the dummy thermal conductive studs with a thermally conductive layer on the QFN package, DFN package, SON package, LGA package, or BGA package.

15. The electronic assembly of claim 13, further comprising a thermally conductive flag disposed over the second encapsulant and over at least a portion of the surface of the component.

16. The electronic assembly of claim 15, further comprising one or more of a solderable metal system (SMS), an organic solderability preservative (OSP), oxidation-resistant metal or metal alloy, or solder ball disposed over the conductive pads, thermally conductive flag, and thermally conductive backside material to resist oxidation over at least a portion of the conductive pads.

17. An electronic assembly, comprising:
a component comprising conductive studs formed over a surface of the component;
a first encapsulant disposed as a single layer of material around four side surfaces of the component, over the surface of the component, and around at least a portion of sidewalls of the conductive studs;
a conductive backside material disposed over at least a portion of a backside of the component;
a substantially planar surface disposed over the surface of the component, wherein the substantially planar surface comprises ends of the conductive studs and a planar surface of the first encapsulant, wherein the planar surface of the first encapsulant comprises a roughness less than 500 nanometers (nm) over a characteristic measurement distance;
conductive structures disposed over the planar surface and configured to be electrically coupled with the component;
a second encapsulant disposed over the conductive structures; and
conductive pads disposed over, or within, the second encapsulant for electrical interconnection.

18. The electric assembly of claim 17, wherein the conductive studs are recessed below the planar surface by 1-1,000 nanometers (nm).

19. The electronic assembly of claim 17, further comprising one or more of a solderable metal system (SMS), an organic solderability preservative (OSP), or oxidation-resistant metal or metal alloy, or solder ball disposed over one or more of the conductive pads, a conductive flag, and the conductive backside material to resist oxidation.

20. The electronic assembly of claim 17, wherein the conductive backside material comprises metal.

21. The electronic assembly of claim 20, wherein the conductive backside material comprises copper with a thickness in a range of 1,000 angstroms to 200 μm.

22. The electronic assembly of claim 17, wherein the conductive backside material extends across a backside of the component and a backside of the encapsulant.

23. The electronic assembly of claim 22, wherein the conductive backside material extends to an edge of the electronic assembly.

24. The electronic assembly of claim 20, wherein the conductive backside material further comprises a pull back from an edge of the electronic assembly.

25. The electronic assembly of claim 17, wherein the conductive backside material is electrically isolated from the component.

26. The electronic assembly of claim 17, wherein the conductive backside material is configured to be electrically coupled to the component.

27. The electronic assembly of claim 26, further comprising:
a portion of the component being formed as an active layer of a semiconductor component; and
a diffusion with a silicide contact or a via coupled with the active layer and extending to the backside of the component.

28. The electronic assembly of claim 17, wherein the conductive backside material is patterned to provide a first portion of material that is configured to be electrically coupled with the component and a second portion of material that is electrically isolated from the component.

29. The electronic assembly of claim 17, additionally comprising a through mold conductive interconnect between a top and bottom conductive flag or conductive layer.

30. The electronic assembly of claim 17, wherein the electronic assembly comprises a face up component and a face down component within the electronic assembly.
